(19) United States
(12) Patent Application Publication
(10) Pub. No.: US 2026/0090315 A1
(43) Pub. Date: Mar. 26, 2026

(54) WET CHEMICAL ETCHING SYSTEM WITH FOUNTAIN DISPENSER

(71) Applicant: ClassOne Technology, Kalispell, MT (US)

(72) Inventors: Craig Meuchel, Kalispell, MT (US); Cody Carter, Kalispell, MT (US); John Ghekiere, Kalispell, MT (US); Alan Murray, Kalispell, MT (US); Josh C. Upole, Kalispell, MT (US)

(21) Appl. No.: 18/894,611

(22) Filed: Sep. 24, 2024

(51) Int. Cl. H01L 21/67

(52) U.S. Cl. CPC H10P 72/0424

(57) ABSTRACT

This document describes wet chemical etching systems designed to apply etching chemistry to a substrate's surface. The system, in some examples, includes a rotor that grips and rotates the substrate, in conjunction with a weir that forms a crest of wet chemistry beneath it. As the substrate rotates, surface tension draws the wet chemistry onto its surface. The system may also include a controller that manages the substrate's movement through different positions.

### TECHNICAL FIELD

This disclosure relates to the manufacture of semiconductor devices.

### BACKGROUND

Semiconductor manufacturing can involve multiple steps to create integrated circuits and other microelectronic devices on a wafer substrate. One step is etching, which selectively removes material from the wafer to form patterns necessary for device functionality. Etching can be performed using wet or dry methods. Wet etching uses liquid chemicals, or etchants, to dissolve materials, while dry etching typically employs gases or plasmas. The choice between wet and dry etching depends on factors such as the desired pattern precision, material properties, and process requirements. Wet etching is often favored for its simplicity, cost-effectiveness, and ability to achieve smooth, isotropic etching profiles. However, it requires control of etchant composition, concentration, temperature, and agitation to ensure uniform and selective material removal.

### SUMMARY

A wet chemical etching system includes a rotor that securely grips a substrate. Positioned beneath the rotor is a weir that defines a slot, allowing a crest of wet chemistry to form. As the substrate rotates, it contacts the crest, and surface tension of the wet chemistry pulls the liquid onto the surface of the substrate.

A system is equipped with a controller that moves the substrate into a first position where it establishes contact with wet chemistry dispensed from a source beneath the substrate. The controller then rotates the substrate, enabling surface tension of the wet chemistry to draw the liquid onto the substrate's surface. After this, the controller moves the substrate to a second position, further away from the dispenser, while ensuring that the wet chemistry continues to be drawn onto the surface.

A system includes a mechanism located beneath the substrate that is specifically designed to dispense a crest of wet chemistry onto the substrate as it rotates.

### BRIEF DESCRIPTION OF THE DRAWINGS

FIG. 1 is a schematic diagram of a conventional wet etching system.

FIG. 2 is a perspective view of a circular nozzle.

FIG. 3 is a side view of the circular nozzle of FIG. 2 with a wafer there above.

FIG. 4A is a perspective view of a slot weir.

FIG. 4B is a perspective view, in cross section, of the slot weir of FIG. 4A.

FIGS. 5, 6, and 7 are plan views of portions of frits.

FIG. 8 is a perspective view, in cross section, of another slot weir.

FIG. 9 is a block diagram of a wet etching system.

### DETAILED DESCRIPTION

Embodiments are described herein. These disclosed embodiments are merely examples, and other embodiments may take different and alternative forms. The figures provided are not necessarily to scale; some features may be exaggerated or minimized to highlight specific details of particular components. Consequently, the structural and functional details disclosed should not be interpreted as limiting but rather as representative examples to guide those skilled in the art.

Various features illustrated and described with reference to any one of the figures may be combined with features shown in other figures to create embodiments that are not explicitly illustrated or described. The combinations of features presented serve as representative embodiments for typical applications. However, various combinations and modifications of these features, consistent with the teachings of this disclosure, may be desirable for particular applications or implementations.

Wet etching is a process in the manufacturing of semiconductor devices, playing a role in the patterning of substrates or films on substrates. It involves the removal of material from a substrate by immersing it in a chemical solution that selectively dissolves the exposed areas. This process is characterized by its use of liquid chemicals, typically acids, bases, or other etchants, to achieve the desired material removal. Wet etching of substrates or films on substrates is common in semiconductor manufacturing. The materials being etched include bulk silicon, silicon oxide, silicon nitride, copper, titanium, tungsten, and various other films.

A goal of wet etching is to create specific patterns on the semiconductor substrate, which can be used to form integrated circuits, microelectromechanical systems (MEMS), and other microstructures. The process begins with the application of a mask, usually made of a photoresist material, to the substrate surface. This mask protects certain areas of the substrate while exposing others to the etchant. The photoresist is patterned using photolithography, a process in which light is used to transfer a geometric pattern from a photomask to the photoresist-coated substrate.

Once the mask is in place, the substrate is immersed in an etchant solution. The choice of etchant depends on the material to be etched and the desired etching characteristics. Common etchants include hydrofluoric acid (HF) for silicon dioxide (SiO2), nitric acid (HNO3) for silicon, and potassium hydroxide (KOH) for silicon nitride (Si3N4). Each etchant has specific properties that make it suitable for etching particular materials. For example, HF is highly effective at etching SiO2 due to its ability to break the strong Si—O bonds, while HNO3 is used for silicon because it can oxidize silicon to form a soluble oxide layer. Of the wet etching processes, bulk silicon etching using an acid mixture is sometimes more difficult than most. This difficulty arises from the need to precisely control the etching conditions to achieve the desired pattern fidelity and device performance.

The etching process can be isotropic or anisotropic. Isotropic etching occurs when the etchant dissolves the material uniformly in all directions, leading to rounded or undercut profiles. This can be advantageous for certain applications where smooth, rounded features are desired. However, isotropic etching can also result in unwanted lateral etching, which can compromise the precision of the pattern. Anisotropic etching, on the other hand, occurs when the etchant preferentially dissolves the material in specific directions. This results in well-defined, vertical sidewalls that support high-resolution patterning in semiconductor devices. Anisotropic etching is often achieved using etchants like KOH, which selectively etches silicon along its crystallographic planes.

Control over the etching process is key to achieving the desired pattern fidelity and device performance. Several factors influence the etching rate and uniformity, including the concentration and temperature of the etchant, the agitation of the solution, and the properties of the substrate material. Higher concentrations of etchant typically result in faster etching rates but can also lead to increased surface roughness and non-uniformity. Temperature is another parameter; increasing the temperature of the etchant solution generally enhances the etching rate but may also introduce unwanted side reactions or degrade the photoresist mask. Agitation, either through stirring or ultrasonic waves, helps to maintain a uniform etchant concentration at the substrate surface and remove reaction byproducts.

Another aspect of wet etching is selectivity, which refers to the ability of the etchant to selectively remove the target material while leaving other materials relatively unaffected. High selectivity is essential for achieving precise patterning, as it ensures that the etchant does not attack the mask or underlying layers. For example, in the etching of SiO2 with HF, the etchant should have high selectivity towards SiO2 over silicon to avoid compromising the silicon substrate. This is often achieved by optimizing the etchant composition and process conditions to favor the dissolution of the target material.

Wet etching also involves several post-etch cleaning steps to remove residual chemicals and byproducts from the substrate surface. These cleaning steps prevent contamination and ensure the integrity of subsequent processing steps. Common cleaning methods include rinsing with deionized water, which helps to remove soluble residues, and the use of solvents or other cleaning agents to dissolve organic contaminants. In some cases, plasma or ultraviolet ozone cleaning may be employed to remove stubborn residues or to further clean the surface at a molecular level.

Etch uniformity is a consideration, particularly for large-scale production where consistent performance across the entire wafer is necessary. Variations in the etching rate can lead to defects and variations in device performance. To achieve uniform etching, control of the process parameters and thorough characterization of the etching behavior are required. This includes understanding the effects of wafer orientation, etchant flow dynamics, and the interaction between the etchant and materials present on the substrate.

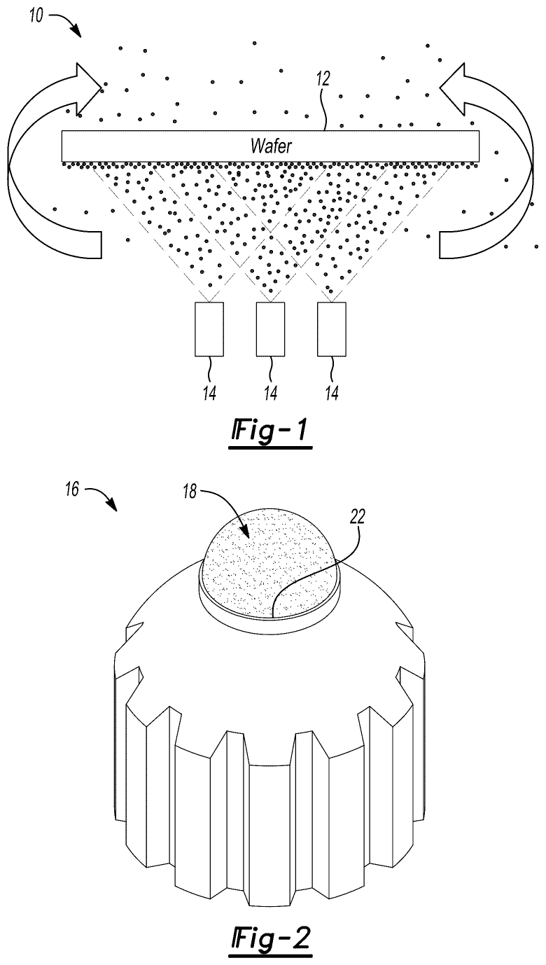

The challenge of maintaining uniform etch pressure across the wafer surface underscores the complexity of achieving consistent etching in practical applications. Referring to FIG. 1, a conventional wet etching system 10 for a wafer 12 includes, among other things, a bank of spray nozzles 14 spaced away from the wafer 12. Such spray nozzles often struggle to provide uniform etch rates due to variations in the impingement pressure of the chemical solution. This issue of etch uniformity is not confined to Si; it also affects other films commonly wet etched in the semiconductor and high-tech industries, including those composed of copper, aluminum, titanium, and other materials.

Additionally, protecting one side of the silicon wafer during processing presents another significant challenge. Often, one side of the wafer must be shielded from the etchant to avoid damaging features necessary for the functionality of the finished product. One method to prevent chemical contact is to place a shield with a seal over the protected side of the wafer. However, if the etchant is under pressure, it can breach the seal. Moreover, the aerosol produced during the process can also compromise the seal, allowing the etchant to reach and attack features on the protected side.

Another problem is the high consumption of etchant during the spraying process. Creating an aerosol requires the chemical to flow through the nozzle at a pressure that meets a certain threshold, necessitating a high flow rate. This high flow rate results in significant chemical consumption, which increases operational costs.

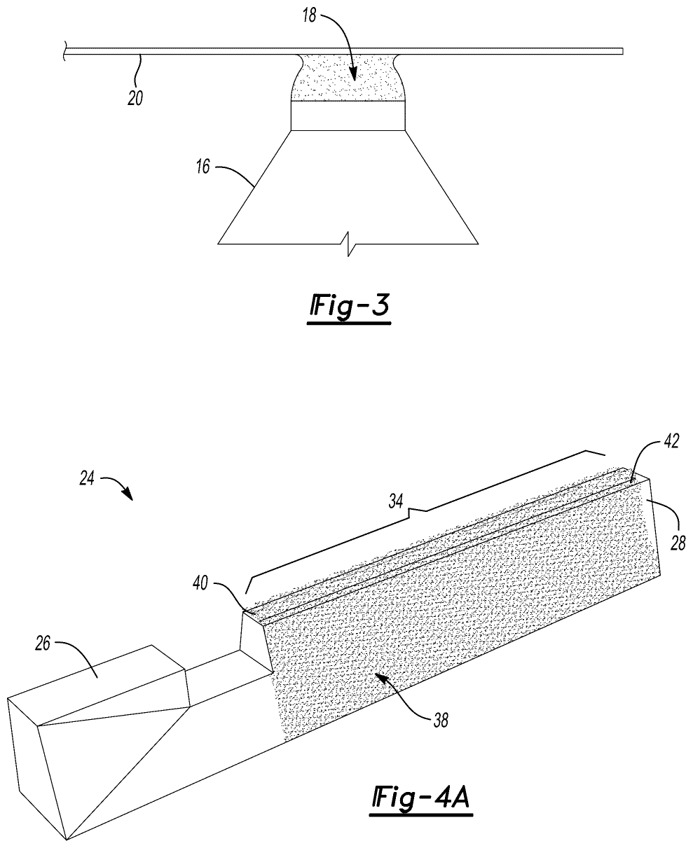

Referring to FIGS. 2 and 3, these issues prompted a switch from a spray nozzle to a circular meniscus nozzle 16. By positioning liquid 18 flowing from this dispenser close to a surface of a wafer 20 and spinning the wafer 20 at high speed, the liquid 18 is drawn up and across the wafer's surface. The combination of surface tension and spin speed leads to improved etch uniformity relative to spraying. Since the pressure of the liquid 18 against the substrate surface is effectively zero, the typical variations in pressure across the substrate may be eliminated.

This arrangement also reduced the pressure of the chemical against the seal. By introducing the chemistry with this technique, the pressure is lowered, resulting in fewer instances of chemical breaches through the seal.

This circular dispensing method could reduce chemical consumption by 75%. Instead of spraying large volumes of chemicals, the flow to the nozzle is controlled at a lower rate. As the chemistry contacts the wafer surface, surface tension draws it onto the surface, while the centrifugal force from the spinning wafer pulls a small amount of chemistry from the circular nozzle.

This technique operates by pushing the chemistry through a large circular orifice 22 positioned close to the wafer surface (e.g., 0-10 mm height of the meniscus). This large orifice 22 ensures that the fluid pressure against the surface is nearly 0 psi. Liquid flow starts after the wafer 20 is correctly positioned (determined by the distance from the circular meniscus nozzle 16). As the liquid's surface tension pulls the chemistry onto the wafer 20, the centrifugal force from spinning the workpiece 20 moves the chemistry to the wafer's edge. This method improved the uniformity of bulk silicon etching from 15% to 5% (as computed by the range divided by 2 times the mean etch amount).

Use of the circular meniscus nozzle 16, even though it may result in improved etch uniformity relative to spraying, can still lead to hotspots or areas with insufficient coverage given that contact with the liquid 18 is concentrated in one spot. Referring to FIGS. 4A and 4B, a slot weir 24 is thus contemplated. It includes a base 26, an applicator 28, and a frit 30. The base 26 defines an input port 32, the applicator 28 defines an output slot 34, and the base 26 and applicator 28 collectively define a conduit 36 fluidly connecting the input port 32 and output slot 34. The frit 30 is located within the conduit 36. Fluid 38 entering through the input port 32 flows through the conduit 36 and passes through the frit 30 before forming a crest 40 at the output slot 34 with any nap 42 flowing over edges of the dispenser.

The frit 30 helps to evenly distribute fluid across the length of the slot 34 even though fluid pressure may drop within the conduit 36 as flow occurs from the base 26 toward the end of the applicator 28 absent the frit 30. Depending on design, the frit 30 may trap particulates and contaminants, allowing only the purified fluid to pass through. It may also prevent backflow, ensuring the flow direction remains consistent and unidirectional. Various materials may be used including ceramic, glass, metal, etc. In this example, the frit 30 is a plate defining a plurality of holes 44. The holes 44 get larger away from the base 26 to account for the pressure drop along the conduit 36. Other designs are also possible.

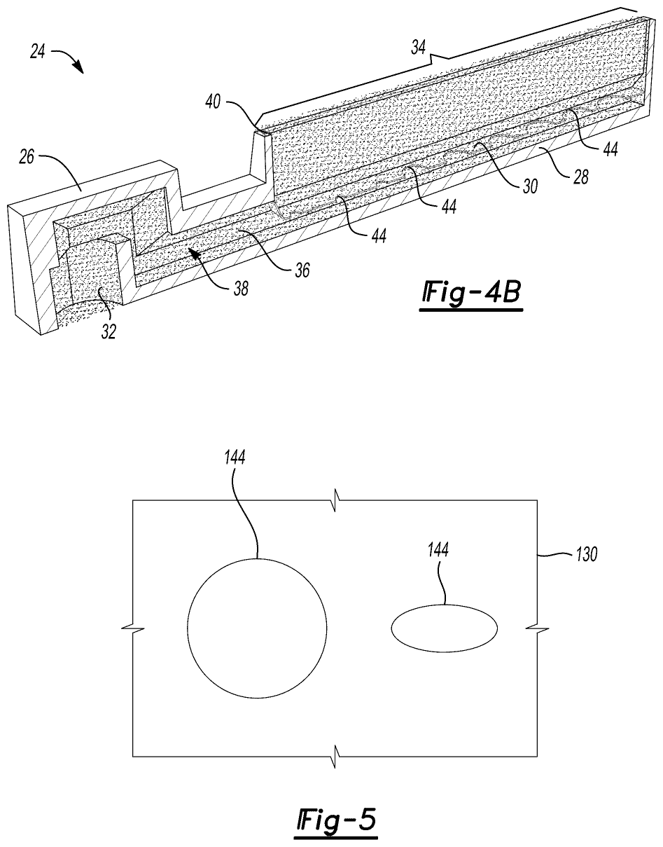

Referring to FIG. 5, a frit 130 may not only have holes 144 of varied sizes but also of different shapes.

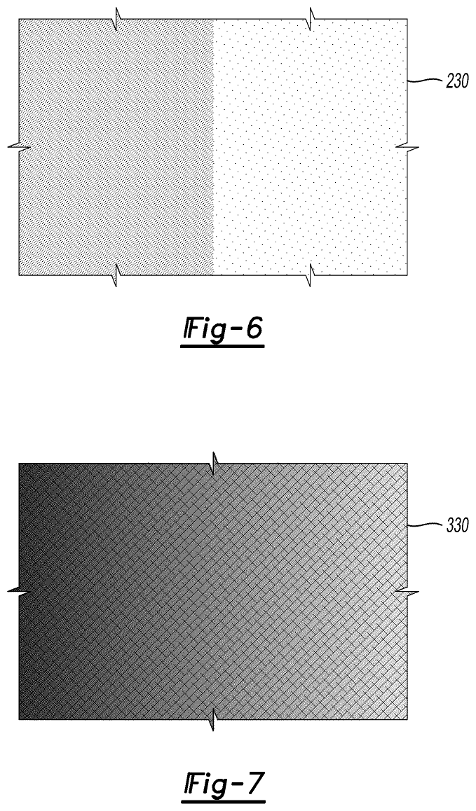

Referring to FIG. 6, a frit 230 may be a porous material, like a metal foam, sintered metals, honeycombs, etc., with differing regions of porosity depending on its intended location within a conduit.

Referring to FIG. 7, a frit 330 may be fibers or a fibrous material, like mesh, woven fabrics, or felts.

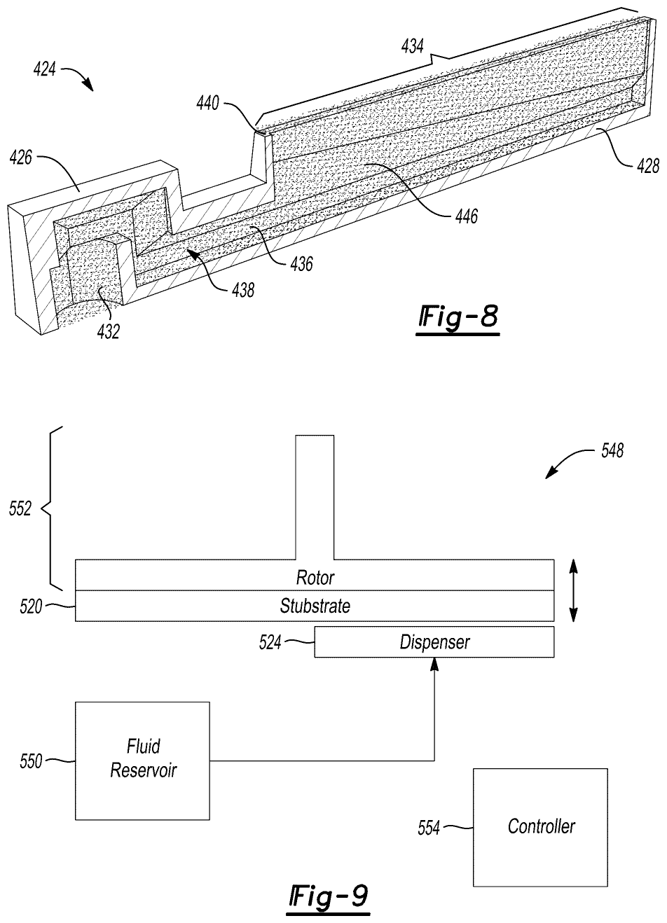

Referring to FIG. 8, a slot weir 424 includes a base 426 and an applicator 428. The base 426 defines an input port 432, the applicator 428 defines an output slot 434, and the base 426 and applicator 428 collectively define a conduit 436 fluidly connecting the input port 432 and output slot 434. This dispenser lacks a frit. Instead, the conduit 436 has a sloped portion 446 in the vicinity of the output slot 434 that decreases in height along its length to account for pressure drops. Fluid 438 entering through the input port 432 flows through the conduit 436 before forming a crest 440 at the output slot 434. The change in height of the sloped portion 446 alters the pressure of the fluid 438 along the applicator 428 such that flow of the fluid 438 exiting the slot 434 and forming the crest 440 is generally uniform.

Referring to FIG. 9, a wet etching system 548 includes, among other things, a dispenser 524, a fluid reservoir 550, a rotor 552, and a controller 554. The fluid reservoir 550 is configured to supply fluid to the dispenser 524. The rotor 552 is configured to hold and rotate the substrate 520 above the dispenser 524. The controller 554 is in communication with and exerts control over the components of the wet etching system 548. The controller 554 is programmed to lower the rotor 552 such that it achieves a predetermined distance (e.g., 4 millimeters, 5 millimeters, etc.) from the dispenser 524. This predetermined distance can depend on the height of the fluid exiting the dispenser 524 such that the substrate 520 establishes contact with the fluid. This lowering operation can be performed before fluid begins to flow through the dispenser 524 or after. With contact established between the substrate 520 and fluid and while the rotor 552 is rotating the substrate 520, the controller 554 is then programmed to raise the rotor 552 a predetermined distance (e.g., 1 millimeter, 6 millimeters) such that the substrate 520 maintains contact with the fluid exiting the dispenser 524 but is now further away from the dispenser 524 than when initial contact with the fluid was made.

The algorithms, methods, or processes disclosed herein can be implemented on a computer, controller, or processing device, which may include any dedicated or programmable electronic control unit. These algorithms, methods, or processes can be stored as executable data and instructions in various forms, such as read-only memory devices (non-writable storage media), and writeable storage media like compact discs, random access memory devices, or other magnetic and optical media. Additionally, they can be executed as software objects. Alternatively, they may be fully or partially embodied in hardware components, such as application-specific integrated circuits (ASICs), field-programmable gate arrays (FPGAs), state machines, or other hardware devices, or a combination of firmware, hardware, and software components.

While the exemplary embodiments described above illustrate certain aspects, they are not intended to encompass all possible variations covered by the claims. The terminology used in this specification is descriptive rather than limiting, allowing for various modifications without departing from the disclosure's spirit and scope. For instance, the terms “controller” and “controllers” may be used interchangeably.

As previously mentioned, features of different embodiments can be combined to create further embodiments not explicitly described or illustrated. Although some embodiments may be described as having advantages or being preferred over other embodiments or prior art implementations for certain characteristics, those skilled in the art understand that trade-offs may be necessary to achieve desired overall system attributes. These attributes can include, but are not limited to, strength, durability, marketability, appearance, packaging, size, serviceability, weight, manufacturability, and ease of assembly. Thus, embodiments considered less desirable for certain characteristics are not excluded from the scope of the disclosure and may be suitable for specific applications.

What is claimed is:

1. A wet chemical etching system comprising:
a rotor configured to grip a substrate; and
a weir beneath the rotor and defining a slot configured to present a crest of wet chemistry such that, during rotation of the substrate while there is contact between the substrate and crest, surface tension of the wet chemistry draws the wet chemistry onto a surface of the substrate.

2. The wet chemical etching system of claim 1, wherein the weir includes a frit.

3. The wet chemical etching system of claim 2, wherein the weir further defines an input port and wherein the frit is disposed between the input port and slot.

4. The wet chemical etching system of claim 2, wherein the frit is perforated.

5. The wet chemical etching system of claim 4, wherein perforations of the frit have varied sizes.

6. The wet chemical etching system of claim 2, wherein the frit is porous.

7. The wet chemical etching system of claim 6, wherein a porosity of the frit is non-uniform.

8. The wet chemical etching system of claim 2, wherein the frit is fibrous.

9. The wet chemical etching system of claim 1 further comprising a controller programmed to, during the rotation, move the substrate away from the weir such that the surface tension continues to draw the wet chemistry onto the surface.

10. A wet chemical etching system comprising:
a controller programmed to move a substrate to a first position to establish contact with wet chemistry flowing from a dispenser beneath the substrate, to rotate the substrate such that surface tension of the wet chemistry draws the wet chemistry onto a surface of the substrate, and to move the substrate to a second position further away from the dispenser than the first position such that the wet chemistry continues to be drawn onto the surface.

11. The wet chemical etching system of claim 10, wherein the dispenser is a weir.

12. A wet chemical etching system comprising:
a rotor configured to grip and rotate a substrate; and
weir means beneath the substrate for dispensing a crest of wet chemistry to the substrate.
